(19) United States
(12) Patent Application Publication
(10) Pub. No.: US 2026/0334055 A1
(43) Pub. Date: Oct. 22, 2026

(54) Display Module and Display Apparatus

(71) Applicants: CHENGDU BOE OPTOELECTRONICS TECHNOLOGY CO., LTD., Chengdu, Sichuan (CN); BOE TECHNOLOGY GROUP CO., LTD., Chaoyang District, Beijing (CN)

(72) Inventors: Shuang Lei, Beijing (CN); Xu Lu, Beijing (CN); Liang Gao, Beijing (CN); Feifan Li, Beijing (CN); Huinan Shi, Beijing (CN); Dianjie Hou, Beijing (CN); Yanli Wang, Beijing (CN); Cha Li, Beijing (CN)

(21) Appl. No.: 19/122,005

(22) PCT Filed: Jun. 21, 2024
(86) PCT No.: PCT/CN2024/100715

§ 371 Date: Apr. 17, 2025

(30) Foreign Application Priority Data
Jul. 26, 2023 (CN) 202310927587.X

(51) Int. Cl. H10K 59/80

(52) U.S. Cl. CPC H10K 59/873

(57) ABSTRACT

A display module includes a display panel. One or more supporting layers, and a driver chip. The display panel includes a main body portion, a bonding portion, and a bending portion between the main body portion and bonding portion. The one or more supporting layers are located between the main body portion and bonding portion and connected to the main body portion and bonding portion. At least one of the one or more supporting layers is provided with a first blocking hole therein. The driver chip is located on a side of the bonding portion away from the main body portion. An orthographic projection of the driver chip on a reference plane at least partially overlaps with an orthogonal projection of the first blocking hole on the reference plane, the reference plane is a plane where the display surface of the main body portion of the display panel is located.

### CROSS-REFERENCE TO RELATED APPLICATIONS

This application is the United States national phase of International Patent Application No. PCT/CN2024/100715, filed Jun. 21, 2024, and claims priority to Chinese Patent Application No. 202310927587.X, filed Jul. 26, 2023, the disclosures of which are hereby incorporated by reference in their entireties.

### BACKGROUND OF THE INVENTION

### Field of the Invention

The present disclosure relates to the field of display technologies, and in particular, to a display module and a display apparatus.

### Description of Related Art

With the rapid development of display technology, display technologies such as liquid crystal display (LCD), organic light emitting display (OLED), quantum dot light emitting display (QLED) and mini/micro light emitting display (MLED) have been widely used in people's daily lives. For example, smart phones, wearable watches, televisions, laptops and car displays have gradually spread in people's lives.

### SUMMARY OF THE INVENTION

In an aspect, a display module is provided. The display module includes a display panel, one or more supporting layers, and a driver chip. The display panel includes a main body portion, a bonding portion, and a bending portion between the main body portion and the bonding portion. The main body portion has a display surface and a non-display surface arranged opposite to each other, and the bending portion is bent toward the non-display surface of the main body portion, so that the bonding portion is bent onto the non-display surface of the main body portion. The one or more supporting layers located between the main body portion and the bonding portion, and connected to the main body portion and the bonding portion. At least one supporting layer of the one or more supporting layers is provided with a first blocking hole therein. The driver chip is located on the bonding portion and on a side of the bonding portion away from the main body portion. An orthographic projection of the driver chip on a reference plane at least partially overlaps with an orthogonal projection of the first blocking hole on the reference plane, the reference plane is a plane where the display surface of the main body portion of the display panel is located.

In some embodiments, the display module includes a plurality of supporting layers. The display module further includes one or more adhesive layers. Two adjacent supporting layers in the plurality of supporting layers have an adhesive layer of the one or more adhesive layers therebetween; among the one or more adhesive layers, at least one adhesive layer is provided with a second blocking hole therein; the orthographic projection of the driver chip on the reference plane at least partially overlaps with an orthogonal projection of the second blocking hole on the reference plane.

In some embodiments, in a direction perpendicular to the main body portion and from the main body portion to the bonding portion, the plurality of supporting layers include a first supporting layer and a second supporting layer, a density of the first supporting layer is greater than a density of the second supporting layer; the second supporting layer is provided with the first blocking hole therein, and the first blocking hole penetrates the second supporting layer.

The one or more adhesive layers include a first adhesive layer, and the first adhesive layer is located between the first supporting layer and the second supporting layer; the first adhesive layer is provided with the second blocking hole therein, and the second blocking hole penetrates the first adhesive layer.

In some embodiments, the orthogonal projection of the first blocking hole on the reference plane substantially coincides with the orthogonal projection of the second blocking hole on the reference plane.

In some embodiments, the orthographic projection of the driver chip on the reference plane is located within an orthogonal projection of a blocking hole on the reference plane, the blocking hole including the first blocking hole; a distance between a boundary of the orthographic projection of the driver chip on the reference plane and a boundary of the orthogonal projection of the blocking hole on the reference plane is greater than or equal to 0.5 mm.

In some embodiments, the display module further includes a heat sink, the heat sink is located in a blocking hole, the blocking hole including the first blocking hole; an orthographic projection of the heat sink on the reference plane at least partially overlaps with the orthographic projection of the driver chip on the reference plane.

In some embodiments, the display module further includes an electromagnetic shielding member located in a blocking hole, the blocking hole including the first blocking hole; an orthographic projection of the electromagnetic shielding member on the reference plane at least partially overlaps with the orthographic projection of the driver chip on the reference plane.

In some embodiments, the display module further includes a buffer member located in a blocking hole, the blocking hole including the first blocking hole; an orthographic projection of the buffer member on the reference plane at least partially overlaps with the orthographic projection of the driver chip on the reference plane.

In some embodiments, the display module further includes a second adhesive layer, and the second adhesive layer includes a first adhesive pattern and a second adhesive pattern. The first adhesive pattern is located between the one or more supporting layers and the bonding portion, and the second adhesive pattern is located between the one or more supporting layers and the bonding portion and between the first adhesive pattern and the bending portion. A thickness of the second adhesive pattern is greater than a thickness of the first adhesive pattern, and the second adhesive pattern and the first adhesive pattern have a spacing therebetween. The driver chip is arranged on a side of the first adhesive pattern away from the main body portion.

In some embodiments, the display module further includes a flexible glass and a first protective layer. The flexible glass is located on the display surface of the main body portion; an orthographic projection of the flexible glass on the reference plane covers an orthographic projection of the display panel on the reference plane, and a boundary of the orthographic projection of the flexible glass on the reference plane and a boundary of the orthographic projection of the display panel on the reference plane have a spacing therebetween. The first protective layer is located on a side of the flexible glass proximate to the display panel; the first protective layer is at least partially located on an edge portion of the flexible glass that extends beyond the display panel, and the first protective layer surrounds the display panel.

In some embodiments, an outer boundary of an orthographic projection of the first protective layer on the reference plane is located outside the boundary of the orthographic projection of the flexible glass on the reference plane.

In some embodiments, an elastic modulus of a material of the first protective layer is less than an elastic modulus of the flexible glass.

In some embodiments, the display module further includes a second protective layer, and the second protective layer is located on a side of the flexible glass away from the display panel and arranged along an edge of the flexible glass; an outer boundary of an orthographic projection of the second protective layer on the reference plane is located outside the boundary of the orthographic projection of the flexible glass on the reference plane.

In some embodiments, a distance between an outer boundary of an orthographic projection of the first protective layer on the reference plane and the boundary of the orthographic projection of the flexible glass on the reference plane is greater than or equal to 0.1 mm; and/or a distance between the outer boundary of the orthographic projection of the second protective layer on the reference plane and the boundary of the orthographic projection of the flexible glass on the reference plane is greater than or equal to 0.1 mm.

In some embodiments, an outer border of the first protective layer is at least partially substantially flush with an outer border of the second protective layer.

In some embodiments, a material of the first protective layer includes polyimide or polyethylene terephthalate; in a case where a second protective layer is included, a material of the second protective layer includes polyimide or polyethylene terephthalate.

In some embodiments, the display module further includes a covering layer and a third adhesive layer. The covering layer is located on a side of the flexible glass away from the display panel, and an orthographic projection of the covering layer on the reference plane covers the orthographic projection of the flexible glass on the reference plane. The third adhesive layer is located between the covering layer and the flexible glass; an orthographic projection of the third adhesive layer on the reference plane is located within the orthographic projection of the flexible glass on the reference plane, and a boundary of the orthographic projection of the third adhesive layer on the reference plane and the boundary of the orthographic projection of the flexible glass on the reference plane have a spacing therebetween. In a case where the display module includes a second protective layer, the second protective layer is at least partially located on an edge portion of the flexible glass that extends beyond the third adhesive layer and surrounds the third adhesive layer.

In some embodiments, the display module further includes a buffer layer located between the flexible glass and the display panel; and/or a light shielding layer located between the flexible glass and the display panel, and the light shielding layer is configured to shield ultraviolet light.

In another aspect, a display apparatus is provided. The display apparatus includes the display module as described in any of the above embodiments and a housing. The display module is located inside the housing.

In some embodiments, the housing includes a bottom plate, a side frame and a top frame. The bottom plate is located on the non-display surface of the display module; the side frame surrounds the bottom plate and is arranged around a periphery of the display module; the top frame is located on the display surface of the display module, the top frame is arranged in a shape of an annulus along an edge of a flexible glass of the display module.

In some embodiments, an inner boundary of an orthographic projection of the top frame on the reference plane is located within an orthographic projection of the flexible glass on the reference plane, and a distance between the inner boundary of the orthographic projection of the top frame on the reference plane and a boundary of the orthographic projection of the flexible glass on the reference plane is greater than or equal to 2 mm.

In some embodiments, the main body portion of the display panel in the display module has a display area and a peripheral area surrounding the display area, and an inner boundary of an orthographic projection of the top frame on the reference plane is located within an orthographic projection of the peripheral area on the reference plane.

### BRIEF DESCRIPTION OF THE DRAWINGS

In order to describe technical solutions in the present disclosure more clearly, the accompanying drawings to be used in some embodiments of the present disclosure will be introduced briefly; obviously, the accompanying drawings to be described below are merely accompanying drawings of some embodiments of the present disclosure, and a person of ordinary skill in the art can obtain other accompanying drawings according to those accompanying drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a structural diagram of another display apparatus, in accordance with some embodiments;

FIG. 3 is a structural diagram of yet another display apparatus, in accordance with some embodiments;

FIG. 4 is a structural diagram of yet another display apparatus, in accordance with some embodiments;

FIG. 5A is a structural diagram of a foldable display apparatus, in accordance with some embodiments;

FIG. 5B is a structural diagram of a foldable display apparatus, in accordance with some embodiments;

FIG. 6 is a sectional view taken along the section line C-C in FIG. 1;

FIG. 7 is a structural diagram of a display module in a flat state, in accordance with some embodiments;

FIG. 8 is a sectional view taken along the section line D-D in FIG. 5A;

FIG. 9 is another sectional view taken along the section line D-D in FIG. 5A;

FIG. 10 is yet another sectional view taken along the section line D-D in FIG. 5A;

FIG. 11 is yet another sectional view taken along the section line D-D in FIG. 5A;

FIG. 12 is yet another sectional view taken along the section line D-D in FIG. 5A;

FIG. 13 is yet another sectional view taken along the section line D-D in FIG. 5A;

FIG. 14 is yet another sectional view taken along the section line D-D in FIG. 5A;

FIG. 15 is yet another sectional view taken along the section line D-D in FIG. 5A;

FIG. 16 is yet another sectional view taken along the section line D-D in FIG. 5A;

FIG. 17 is a flowchart of a method for forming a first protective layer, in accordance with some embodiments;

FIG. 18 is a flowchart of a method for forming a second protective layer, in accordance with some embodiments;

FIG. 19 is yet another sectional view taken along the section line D-D in FIG. 5A;

FIG. 20 is yet another sectional view taken along the section line D-D in FIG. 5A;

FIG. 21 is yet another sectional view taken along the section line D-D in FIG. 5A;

FIG. 22 is a structural diagram of a display module in a folded state, in accordance with some embodiments;

FIG. 23 is yet another sectional view taken along the section line D-D in FIG. 5A;

FIG. 24 is yet another sectional view taken along the section line D-D in FIG. 5A;

FIG. 25 is yet another sectional view taken along the section line D-D in FIG. 5A; and

FIG. 26 is yet another sectional view taken along the section line D-D in FIG. 5A.

### DESCRIPTION OF THE INVENTION

The technical solutions in some embodiments of the present disclosure will be described clearly and completely below with reference to the accompanying drawings, and obviously, the described embodiments are merely some but not all embodiments of the present disclosure. All other embodiments obtained by a person of ordinary skill in the art based on embodiments provided in the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example”, or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described may be included in any one or more embodiments or examples in any suitable manner.

Terms such as “first” and “second” are used herein to describe various elements, but the elements should not be limited by the terms. These terms are only used to distinguish one component from other components. For example, an element referred to as a first element in an embodiment could be referred to as a second element in another embodiment without departing from the scope of the appended claims. Unless mentioned otherwise, terms in the singular may include plural forms.

In the description of some embodiments, the term “connect” and derivatives thereof may be used. The term “connected” should be understood in a broad sense; for example, the term “connected” may represent a fixed connection, a detachable connection or a one-piece connection, or may represent a direct connection or an indirect connection through an intermediate medium.

The phrase “at least one of A, B and C” has the same meaning as the phrase “at least one of A, B or C”, and they both include the following combinations of A, B and C, only A, only B, only C, a combination of A and B, a combination of A and C, a combination of B and C, and a combination of A, B and C.

The phrase “A and/or B” includes the following three combinations, only A, only B, and a combination of A and B.

The phrase “applicable to” or “configured to” used herein means an open and inclusive expression, which does not exclude devices that are applicable to or configured to perform additional tasks or steps.

As used herein, “about” or “approximately” is inclusive of the stated value and means within an acceptable range of deviation for the particular value as determined by one of ordinary skill in the art, taking into account the measurements in question and the errors associated with measurement of a particular quantity (i.e., limitations of the measurement system). For example, “about” may mean within one or more standard deviations, or within ±30%, ±20%, ±10%, ±5% of the stated value.

The term such as “parallel”, “perpendicular” or “equal” as used herein includes a stated condition and a condition similar to the stated condition, the range of the similar condition is within an acceptable range of deviation, and the acceptable range of deviation is determined by, for example, a person of ordinary skill in the art, considering measurement in question and errors (i.e., limitations of a measurement system) associated with measurement of a particular quantity. For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, a difference between two equals being less than or equal to 5% of either of the two equals.

It will be understood that, when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plan views that are schematic illustrations of idealized embodiments. In the accompanying drawings, thicknesses of layers and sizes of regions are enlarged for clarity. Variations in shape relative to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature being curved. Therefore, the regions shown in the accompanying drawings are schematic in nature, and their shapes are not intended to show actual shapes of the regions in a device, and are not intended to limit the scope of the exemplary embodiments.

It will be noted that, unless otherwise defined, all terms (including technical and scientific terms) used in embodiments of the present disclosure have the same meaning as commonly understood by a person of ordinary skill in the art. It will be further understood that unless expressly defined herein, terms (e.g., terms defined in commonly used dictionaries) should be interpreted as having a meaning that is consistent with their meaning in the context of the relevant art, and should not be interpreted as an ideal or overly formal meaning.

In the present disclosure, terms such as “lower”, “below”, “above”, “upper” and the like are used to explain the relational association of components shown in the drawings. Terms may be relative concepts and described based on directions indicated in the drawings, but are not limited thereto.

The term “overlap” or “overlapping” means that a first object may be above or below of a second object, or at the side of a second object, and vice versa. Additionally, the term “overlap” may include layering, stacking, facing or toward, extending over, covering or partially covering, or any other suitable term that would be appreciated and understood by one of ordinary skill in the art.

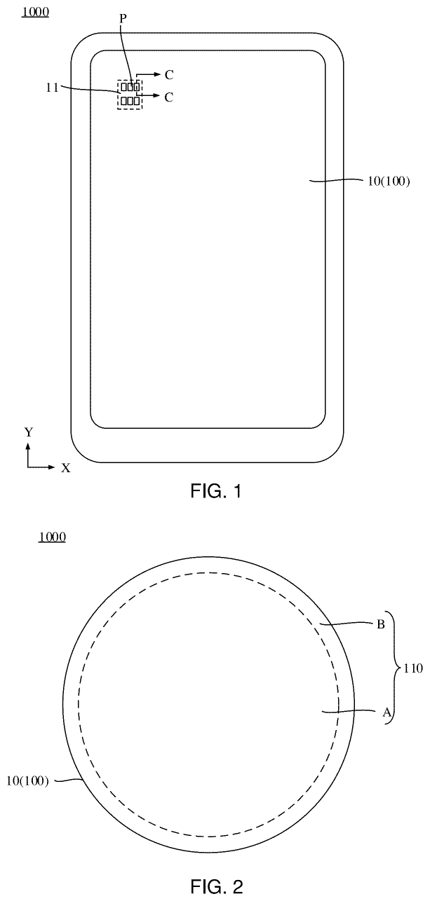

As shown in FIG. 1, some embodiments of the present disclosure provide a display apparatus 1000, and the display apparatus 1000 may be any apparatus that displays images whether in motion (e.g., videos) or stationary (e.g., static images), and whether textual or graphical.

For example, the display apparatus 1000 may be any product or component having a display function, such as a television, a notebook computer, a tablet computer, a mobile phone, a personal digital assistant (PDA), a navigator, a vehicle device, a flight device, a wearable device, or a virtual reality (VR) device.

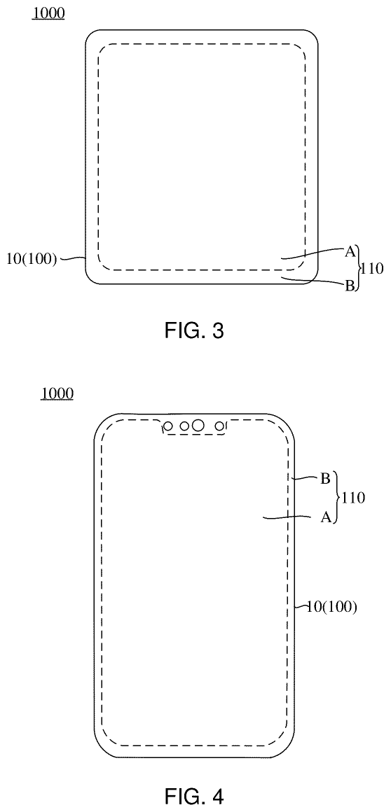

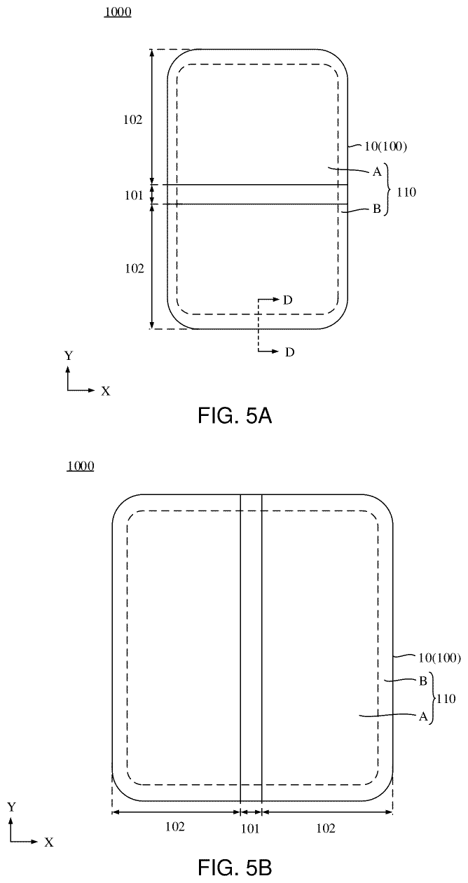

As another example, as shown in FIGS. 2 and 3, the display apparatus 1000 may be a wearable device, which may be a circular watch as shown in FIG. 2 or a square watch as shown in FIG. 3. For another example, the display apparatus 1000 may be a mobile phone, and the mobile phone may be a bar mobile phone as shown in FIG. 4, or a foldable mobile phone as shown in FIGS. 5A and 5B.

The display apparatus 1000 may be any one of a flat display apparatus, a curved display apparatus, a foldable display apparatus, or a rollable display apparatus.

Some embodiments of the present disclosure will be schematically described below by taking an example in which the display apparatus 1000 is a foldable display apparatus, but the embodiments of the present disclosure are not limited thereto, and any other display apparatuses 1000 may also be taken into consideration as long as the same technical concept is applied.

The foldable display apparatus 1000 includes an inner foldable display apparatus and an outer foldable display apparatus.

In some embodiments, as shown in FIG. 1, the display apparatus 1000 includes a display module 100. The display module 100 includes a display panel 10.

The display panel 10 may be an organic light-emitting diode display panel, a quantum dot light-emitting diode display panel, a micro/mini light-emitting diode display panel, a liquid crystal display panel, a plasma display panel, a field emission display panel, an electrowetting display panel or an electrophoretic display panel, etc., and the embodiments of the present disclosure are not specifically limited here.

Some embodiments of the present disclosure are exemplarily illustrated by taking an example where the display panel 10 is an organic light-emitting diode display panel below, but the implementations of the present disclosure include but are not limited thereto, and any other display panels may also be considered as long as the same technical concept is applied.

As shown in FIGS. 1 and 6, the display panel 10 includes: a substrate 11, and a plurality of sub-pixels P and an encapsulation layer 12 that are arranged on the substrate 11.

For example, the substrate 11 is a flexible substrate, and the flexible substrate may be a polyethylene terephthalate (PET) substrate, a polyethylene naphthalate (PEN) substrate, or a polyimide (PI) substrate.

In some embodiments, referring to FIG. 1, the plurality of sub-pixels P may be arranged in, for example, a plurality of rows and a plurality of columns, a row of sub-pixels P includes multiple sub-pixels P arranged in a first direction X, and a column of sub-pixels P includes multiple sub-pixels P arranged in a second direction Y. The first direction X is substantially perpendicular to the second direction Y.

The plurality of sub-pixels P may include first sub-pixels that emit light of a first color, second sub-pixels that emit light of a second color, and third sub-pixels that emit light of a third color. The first color, the second color, and the third color are three primary colors. For example, the first color is red, the second color is blue, and the third color is green, which is not specifically limited in the embodiment of the present disclosure.

As shown in FIG. 6, each sub-pixel P includes a pixel circuit 14 and a light-emitting device 15 that are disposed on the substrate 11.

The pixel circuit 14 includes a plurality of thin film transistors 141 and storage capacitor(s) 142.

In some embodiments, the thin film transistor 141 is, for example, an oxide thin film transistor. The oxide thin film transistor has a high carrier mobility, which may improve the response speed of the thin film transistor 141.

The thin film transistor 141 includes an active layer 1411, a source 1412, a drain 1413 and a gate 1414, and the source 1412 and the drain 1413 are both in contact with the active layer 1411. The storage capacitor 142 includes a first electrode plate 1421 and a second electrode plate 1422.

It will be noted that the source 1412 and the drain 1413 may be interchanged, that is, in FIG. 6, the reference sign “1412” represents the drain, and the reference sign “1413” represents the source.

As shown in FIG. 6, the light-emitting device 15 includes a first electrode 151, a light-emitting functional layer 152 and a second electrode 153; the first electrode 151 is electrically connected to, for example, a source 1412 or drain 1413 of a thin film transistor 141 in the plurality of thin film transistors 141 that serves as a driving transistor, FIG. 6 is illustrated by taking an example in which the first electrode 151 is electrically connected to the drain 1413 of the thin film transistor 141. A material of the first electrode layer 151 includes indium tin oxide (ITO) or silver (Ag). A material of the second electrode includes aluminum (AI), Ag or magnesium (Mg).

It will be noted that the first electrode 151 is an anode of the light-emitting device 15, and the second electrode 153 is a cathode of the light-emitting device 15; alternatively, the first electrode 151 is the cathode of the light-emitting device 15, and the second electrode 153 is the anode of the light-emitting device 15. The embodiments of the present disclosure are described below by taking an example where the first electrode 151 is the anode of the light-emitting device 15 and the second electrode 153 is the cathode of the light-emitting device 15. For example, as shown in FIG. 6, the second electrode 153 (cathode) is a whole-layer structure, that is, voltage values of the second electrodes 321 of different light-emitting devices 15 are equal.

The light-emitting functional layer 152 may include only a light-emitting layer; or in addition to the light-emitting layer, the light-emitting functional layer 152 further includes at least one of an electron transporting layer (ETL), an electron injection layer (EIL), a hole transporting layer (HTL) and a hole injection layer (HIL).

The encapsulation layer 12 is located on a side of the second electrode layer 152 away from the substrate 151. The encapsulation layer 12 may be an encapsulation film(s). In some embodiments, the encapsulation layer 12 includes one encapsulation film, or includes two or more encapsulation films that are stacked. For example, the encapsulation layer includes three encapsulation films that are stacked in sequence.

In the case where the encapsulation layer 12 includes three encapsulation films that are stacked in sequence, an encapsulation film located in the middle is made of an organic material, and encapsulation films located at two sides are made of an inorganic material. The organic material is, for example, polymethyl methacrylate (PMMA) or PI.

As shown in FIGS. 1 to 5B, the display panel 10 has a display area A and a peripheral area B disposed on at least one side of the display area A. FIGS. 1 to 5B are illustrated by taking an example in which the peripheral area B is disposed around the display area A.

As shown in FIG. 1, the display area A is an area where images are displayed, and is configured to be provided a plurality of pixel unit 13 therein; the peripheral area B is an area where no image is displayed, and is configured to be provided with display driving circuits, such as gate driving circuit(s) and source driving circuit(s).

Based on the above embodiments, the display panel 10 includes at least one bendable region 101 and at least two unbending regions 102.

In some examples, as shown in FIGS. 5A and 5B, the display panel 10 may include one bendable region 101 and two non-bending regions 102.

For example, as shown in FIG. 5A, the bendable region 101 extends in the first direction X, and the two non-bending regions 102 are respectively arranged on both sides of the bendable region 101 in the second direction Y. Two adjacent non-bending regions 102 are connected by a bendable region 101. That is, at least two non-bending regions 102 are arranged at intervals in the second direction Y, and any two adjacent non-bending regions 102 are connected by a bendable region 101.

Alternatively, for example, as shown in FIG. 5B, the bendable region 101 extends in the second direction Y, and the two non-bending regions 102 are respectively arranged on both sides of the bendable region 101 in the first direction X. Two adjacent non-bending regions 102 are connected by a bendable region 101. That is, at least two non-bending regions 102 are arranged at intervals in the first direction X, and any two adjacent non-bending regions 102 are connected by a bendable region 101.

As shown in FIGS. 5A and 5B, some embodiments of the present disclosure are exemplarily illustrated by taking an example in which the display panel 10 includes one bendable region 101 and two non-bending regions 102, but the implementations of the present disclosure are not limited thereto, and an display panel 10 including a plurality of bendable regions 101 and a plurality of non-bending regions 102 may also be considered as long as the same technical concept is applied.

For example, as shown in FIGS. 5A and 5B, the two non-bending regions 102 may be arranged symmetrically with respect to the bendable region 101, so that ends of the two non-bending regions 102 away from the bendable region 101 are flush with each other after the display panel 10 is bent.

In addition, in the case where the display apparatus 1000 is an inward-foldable display apparatus 1000, after the display panel 10 is bent inward, the two non-bending regions 102 of the display panel 10 are stacked face to face. In the case where the display apparatus is an outward-foldable display apparatus 1000, the two non-bending regions 102 of the display panel 10 are stacked back to back.

It will be understood that, during a bending (curling or folding) process of the display panel 10, the bendable region 101 is bent, and the non-bending regions 102 remains in a flat state. It can be understood that the bendable region 101 and the non-bending regions 102 are demarcated based on whether deformation occurs during the bending process of the display apparatus, and the structures of the two may be the same.

For example, in a process for manufacturing the display panel 10, a plurality of sub-pixels P are formed on a same substrate 11, such as a substrate made of polyimide; then, the display panel 10 is divided into a first region and second regions arranged on both sides of the first region. The substrate 11 and sub-pixels P included in the first region constitute the bendable region 101, and the substrate 11 and sub-pixels P included in the second region constitute the non-bending region 102.

As can be seen from the above, the bendable region 101 and the non-bending region 102 may be the same in structure, but the two are in different states when the display panel 10 is bent. For example, during the bending process of the display panel 10, the bendable region 101 will be bent accordingly, and the non-bending region 102 remains in its original state (in the flat state).

In some embodiments, as shown in FIG. 7, the display module 100 may include a circuit board 20, and the circuit board 20 may be bonded to the display panel 10 at an end of the display panel 10.

In some embodiments, as shown in FIG. 7, the display panel 10 includes a main body portion 110, a bending portion 120 and a bonding portion 130 that are connected in sequence, the bending portion 120 is located on a side of the main body portion 110, and the bonding portion 130 is located on a side of the bending portion 120 away from the main body portion 110; that is, the bending portion 120 is located between the main body portion 110 and the bonding portion 130.

As shown in FIG. 7, the main body portion 110 may be a portion of the display panel 10 for displaying images. That is to say, the display area A (as shown in FIGS. 2 to 5B) is located in the main body portion 110, that is, the main body portion 110 has the display area A (as shown in FIGS. 2 to 5B).

As shown in FIG. 7, the main body portion 110 has a display surface 110A and a non-display surface 110B that are opposite to each other. It should be noted that the display surface 110A refers to a side of the main body portion 110 displaying an image (the upper side of the main body portion 110 in FIG. 7), and the non-display surface 110B refers to the other side opposite to the display surface 110A (the lower side of the main body portion 110 in FIG. 7).

As shown in FIGS. 2 to 5B, the main body portion 110 may further include a part of the peripheral area B. For example, as shown in FIGS. 2 to 5B, an orthographic projection of the main body portion 110 on the reference plane is substantially in a shape of any one of a circle, an ellipse, a rectangle, etc., which is not specifically limited in the embodiments of the present disclosure.

It will be noted that the reference plane is a plane where a display surface of the main body portion 110 of the display panel 10 is located. The display surface refers to a surface of the main body portion 110 used for displaying image information.

Herein, “substantially in a shape of a circle or an ellipse” refers to being in a shape of a circle or ellipse as a whole, but is not limited to a standard circle or ellipse. That is, “circle or ellipse” herein includes not only the shape of a basic circle or ellipse, but also a shape similar to a circle or ellipse.

Herein, “substantially in a shape of a rectangle” refers to being in a shape of a rectangle as a whole, but is not limited to a standard rectangle. That is, “rectangle” herein includes not only the shape of a basic rectangle, but also a shape similar to a rectangle. For example, the long and short sides of the rectangle are curved at each intersecting position (i.e., at each corner), i.e., the corners are smooth and the shape is a rounded rectangle. The following description will be made by taking an example in which the orthographic projection of the main body portion 110 on the reference plane shown in FIGS. 5A and 5B is substantially a rounded rectangle.

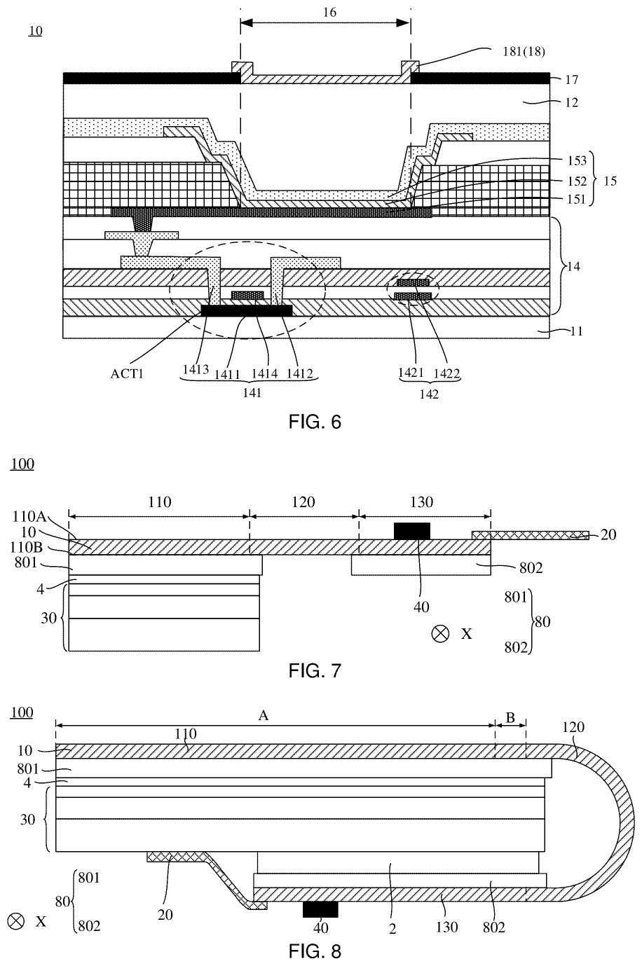

As shown in FIG. 7, the bonding portion 130 may be a portion of the display panel 10 used for bonding the circuit board 20. As shown in FIG. 8, by a bending process, the bending portion 120 is bent in a bending axis extending in the first direction X toward the non-display surface 110B of the main body portion 110 of the display panel 10, so that the bonding portion 130 is bent onto the non-display surface 110B of the main body portion 110, so as to reduce the bezel of the display apparatus 1000 (as shown in FIGS. 5A and 5B). The bending axis is not an actual structure existing in the display panel 10, but is only a concept proposed to illustrate the bending process of the display panel 10.

As shown in FIG. 8, after the bonding portion 130 is bent, the circuit board 20 may be bent along with the display panel 10 onto the non-display surface 110B of the main body portion 110, so as to reduce the bezel of the display apparatus 1000. As shown in FIG. 8, part of the circuit board 20 is located on a side of the main body portion 110 proximate to the bonding portion 130 and bonded to the main body portion 110, and part of the circuit board 20 is located on a side of the bonding portion 130 away from the main body portion 110 and bonded to the bonding portion 130.

It will be noted that a bending radius of the bending portion 120 may be in a range of 0.1 mm to 0.5 mm; for example, the bending radius of the bending portion 120 may be any one of 0.1 mm, 0.2 mm, 0.3 mm, 0.35 mm, 0.4 mm and 0.5 mm.

It will be understood that the smaller the bending radius of the bending portion 120 is, the narrower the bezel (e.g., the lower bezel in FIGS. 5A and 5B) of the display apparatus 1000 corresponding to the bending portion 120 may be designed to be, which is more conducive to the narrow bezel design of the display apparatus 1000. For example, the bending radius of the bending portion 120 may be in a range of 0.1 mm to 0.2 mm. For example, the bending radius of the bending portion 120 may be any one of 0.12 mm, 0.15 mm and 0.18 mm, so that the bezel (e.g., the lower bezel in FIGS. 5A and 5B) of the display apparatus 1000 corresponding to the bending portion 120 may be made narrower.

Based on the above embodiments, as shown in FIG. 8, the display module 100 further includes at least one supporting layer 30 and a driver chip 40.

As shown in FIG. 8, at least one supporting layer 30 is located between the main body portion 110 and the bonding portion 130, and at least one supporting layer 30 is connected to the main body portion 110 and the bonding portion 130. The supporting layer 30 is configured to support the display panel. The material of the supporting layer 30 may include at least one of stainless steel, aluminum, or copper.

As shown in FIG. 8, the at least one supporting layer 30 is bonded to the main body portion through a fourth adhesive layer 4. A material of the fourth adhesive layer 4 includes optically clear adhesive (OCA), or pressure-sensitive adhesive (PSA). For example, the at least one supporting layer 30 is bonded to the main body portion 110 through a pressure-sensitive adhesive.

As shown in FIG. 8, the at least one supporting layer 30 is bonded to the bonding portion 130 through a second adhesive layer 2. A material of the second adhesive layer 2 includes foam adhesive or mesh adhesive. For example, the at least one supporting layer 30 is bonded to the bonding portion 130 through the mesh adhesive.

Here, the mesh adhesive includes a plurality of intersecting vertical and horizontal lines. The arrangement of the horizontal and vertical lines in the mesh adhesive allows the air between the mesh adhesive and the supporting layer 30 or bonding portion 130 to be discharged well when the mesh adhesive is pasted, thereby reducing the probability of bubble generation. As a result, the mesh adhesive may be flat when it is attached to the supporting layer 30 or the bonding portion 130, so that the tightness of the bonding between the supporting layer 30 and the bonding portion 130 may be improved.

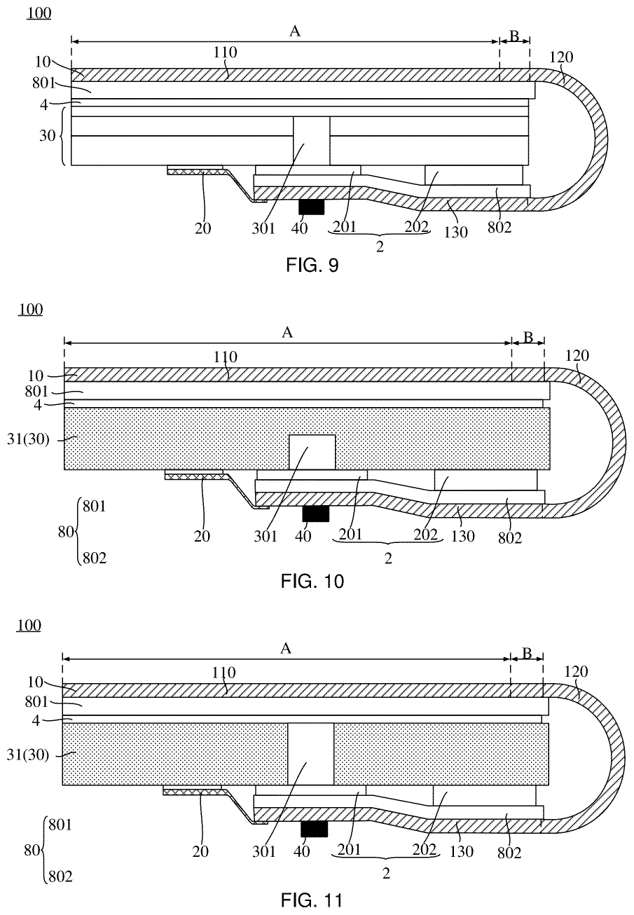

For example, as shown in FIG. 9, the second adhesive layer 2 includes a first adhesive pattern 201 and a second adhesive pattern 202. The first adhesive pattern 201 is located between the at least one supporting layer 30 and the bonding portion 130, and is bonded to the at least one supporting layer 30 and the bonding portion 130. The second adhesive pattern 202 is located between the at least one supporting layer 30 and the bonding portion 130, and is bonded to the at least one supporting layer 30 and the bonding portion 130. The second adhesive pattern 202 is also located between the first adhesive pattern 201 and the bending portion 120. The second adhesive pattern 202 has a thickness greater than that of the first adhesive pattern 201, and the second adhesive pattern 202 and the first adhesive pattern 201 have a gap therebetween.

With such an arrangement, there is a large space on a side of a part of the bonding portion 130 bonded to the first adhesive pattern 201 away from the main body portion 110; that is, as shown in FIG. 9, the space below the part of the bonding portion 130 bonded to the first adhesive pattern 201 is large, thereby providing installation space for other devices such as a driver chip 40 and a circuit board 20.

As shown in FIG. 8, the driver chip 40 is used to provide the display panel 10 with data signals required for displaying images.

As shown in FIGS. 8 and 9, the driver chip 40 may be disposed on the bonding portion 130, so that the driver chip 40 may provide the data signals required for displaying images for the main body portion 110 through the bonding portion 130 and the bending portion 120 to control the display panel 10 to display images.

Here, the driver chip 40 includes at least one of microchips such as a source driver chip, a touch chip, a timing controller, and a gamma circuit, which is not specifically limited in the embodiments of the present disclosure.

As shown in FIG. 9, on the basis of the above embodiments, and in the case where the second adhesive layer 2 includes a first adhesive pattern 201 and a second adhesive pattern 202, the driver chip 40 is arranged on a side of the first adhesive pattern 201 away from the main body portion 110, that is, an orthographic projection of the driver chip 40 on the reference plane is located within an orthographic projection of the first adhesive pattern 201 on the reference plane.

With such arrangement, the thickness of the display module 100 may be reduced, which facilitates the thinness and lightness of the display apparatus 1000.

For example, a difference between the thickness of the second adhesive pattern 202 and the thickness of the first adhesive pattern 201 is greater than or equal to the thickness of the driver chip 40.

That is, after the driver chip 40 is installed, a surface of the driver chip 40 away from the main body portion 110 is closer to the main body portion 110 than a surface of a part of the bonding portion 130 that is bonded to the second adhesive pattern 202. Alternatively, the surface of the driver chip 40 away from the main body portion 110 is substantially flush with the surface of the part of the bonding portion 130 that is bonded to the second adhesive pattern 202.

In this case, the thickness of the display module 100 may be further reduced.

In the related art, when a force is applied to the main body portion, the force will cause the main body portion to deform, and the deformation may be transmitted to the driver chip through the main body portion, the at least one supporting layer and the bonding portion, thereby causing the driver chip to deform and thus damage the driver chip.

In order to solve the above problem, as shown in FIG. 9, in the embodiments of the present disclosure, at least one supporting layer 30 is provided with a first blocking hole 301, and the orthographic projection of the driver chip 40 on the reference plane at least partially overlaps with an orthographic projection of the first blocking hole 301 on the reference plane. The first blocking hole 301 may be a blind hole or a through hole.

In this way, the first blocking hole 301 may prevent the deformation of the main body portion 110 from being transmitted to the driver chip 40, thereby reducing the risk of deformation of the driver chip 40 and the risk of damage to the driver chip 40.

In some embodiments, as shown in FIG. 10, the display module 100 includes one supporting layer 30; that is, the display module 100 includes a first supporting layer 31; the first supporting layer 31 is located between the main body portion 110 and the bonding portion 130, and an orthographic projection of the first supporting layer 31 on the reference plane covers at least an orthographic projection of the display area A on the reference plane. The first supporting layer 31 and the main body portion 110 are bonded together through the fourth adhesive layer 4, and the first supporting layer 31 and the bonding portion 130 are bonded together through the second adhesive layer 2. The first supporting layer 31 is provided with a first blocking hole 301.

For example, as shown in FIG. 10, the first blocking hole 301 is a blind hole, and the opening direction of the blind hole is toward the bonding portion 130, that is, a surface of the first supporting layer 31 proximate to the bonding portion 130 has an opening, and a surface of the first supporting layer 31 away from the bonding portion 130 has no opening.

In this case, each region within the outer border of the first supporting layer 31 is filled with the first supporting layer 31. When the main body portion 110 is subjected to a force, each part of the main body portion 110 located in the display area A may be supported by the first supporting layer 31, so that the surface of the main body portion 110 located in the display area A proximate to the first supporting layer 31 may be relatively flat, i.e., there is no height difference between the surface of the main body portion 110 in the display area A and the first supporting layer 31. As a result, the risk of film printing on the display panel 10 is reduced.

Alternatively, for example, as shown in FIG. 11, the first blocking hole 301 is a through hole. Thus, the first blocking hole 301 has a large dimension in a direction perpendicular to the main body portion 110, which may further prevent the deformation of the main body portion 110 from being transmitted to the driver chip 40, thereby reducing the risk of deformation of the driver chip 40 and reducing the risk of damage to the driver chip 40.

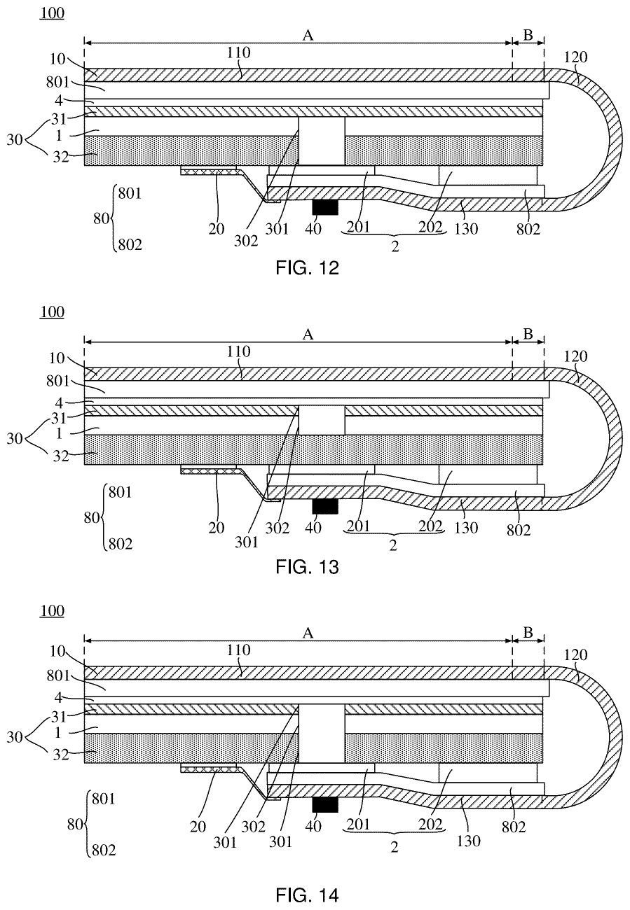

In some other embodiments, as shown in FIG. 12, the display module 100 includes a plurality of supporting layers 30 and at least one adhesive layer.

The plurality of supporting layers 30 are located between the main body portion 110 and the bonding portion 130, and the plurality of supporting layers 30 are connected to the main body 110 and the bonding portion 130. There is an adhesive layer between two adjacent supporting layers 30 in the plurality of supporting layers 30, and the two adjacent supporting layers 30 are bonded together by the adhesive layer. Among the at least one adhesive layer (all adhesive layers between the plurality of supporting layers 30), there is at least one adhesive layer has a second blocking hole 302, and the orthographic projection of the driver chip 40 on the reference plane at least partially overlaps with an orthogonal projection of the second blocking hole 302 on the reference plane.

With such configuration, the second blocking hole 302 may prevent the deformation of the main body portion 110 from being transmitted to the driver chip 40, thereby reducing the risk of deformation of the driver chip 40 and the risk of damage to the driver chip 40.

In some examples, as shown in FIG. 12, in a direction perpendicular to the main body portion 110 and directed from the main body portion 110 to the bonding portion 130, the plurality of supporting layers 30 includes a first supporting layer 31 and a second supporting layer 32, and the density of the first supporting layer 31 is greater than the density of the second supporting layer 32. For example, the material of the first supporting layer 31 includes stainless steel, and the material of the second supporting layer 32 includes titanium or aluminum.

In this way, the weight of the plurality of supporting layers 30 may be reduced, thereby reducing the weight of the display module 100, which facilitates the lightness and thinness of the display apparatus 1000. The first supporting layer 31 and the main body portion 110 are bonded together by the fourth adhesive layer 4, and the second supporting layer 32 and the bonding portion 130 are bonded together by the second adhesive layer 2.

On this basis, in order to reduce the weight of the plurality of supporting layers 30 and ensure the supporting strength of the plurality of supporting layers 30. The thickness of the first supporting layer 31 is in a range of approximately 30 μm to approximately 200 μm, inclusive, and the thickness of the second supporting layer 32 is in a range of approximately 150 μm to approximately 200 μm, inclusive.

For example, the thickness of the first supporting layer 31 is any one of 30 μm, 36 μm, 40 μm, 60 μm, 65 μm, 75 μm, 83 μm, 90 μm, and 100 μm; the thickness of the second supporting layer 32 is any one of 150 μm, 155 μm, 161 μm, 168 μm, 172 μm, 180 μm, 185 μm, 194 μm, and 200 μm.

For example, as shown in FIG. 12, only the second supporting layer 32 is provided with the first blocking hole 301, and the first blocking hole 301 penetrates the second supporting layer 32.

With such arrangement, each region within the outer border of the first supporting layer 31 is filled with the first supporting layer 31, and when the main body portion 110 is subjected to a force, each part of the main body portion 110 located in the display area A may be supported by the first supporting layer 31, so that the surface of the main body portion 110 located in the display area A proximate to the first supporting layer 31 may be relatively flat, so as to reduce the risk of film printing in the display area A.

Furthermore, since the thickness of the second supporting layer 32 is greater than that of the first supporting layer 31, the second supporting layer 32 is provided with a first blocking hole 301, and the first blocking hole 301 penetrates the second supporting layer, so that the dimension of the first blocking hole 301 in a direction perpendicular to the main body portion 110 may be great, which may further block the deformation generated by the main body portion 110 from being transmitted to the driver chip 40, thereby reducing the risk of deformation of the driver chip 40 and reducing the risk of damage to the driver chip 40.

Alternatively, for example, as shown in FIG. 13, only the first supporting portion 31 is provided with the first blocking hole 301.

In this way, since the density of the first supporting layer 31 is relatively high, arranging the first blocking hole 301 in the first supporting layer 31 may greatly reduce the weight of the plurality of supporting layers 30 to a great extent. As a result, it is possible to reduce the weight of the display module 100, which facilitates the thinness and lightness of the display apparatus 1000.

Alternatively, for example, as shown in FIG. 14, the first supporting layer 31 is provided with a first blocking hole 301, and the second supporting layer 32 is provided with a first blocking hole 301.

With such arrangement, the dimension of the first blocking hole 301 in the direction perpendicular to the main body portion 110 is great, which may further block the deformation of the main body portion 110 from being transmitted to the driver chip 40, thereby reducing the risk of deformation of the driver chip 40 and reducing the risk of damage to the driver chip 40.

In addition, as shown in FIGS. 12 to 14, the at least one adhesive layer includes one adhesive layer, that is, the display module 100 includes a first adhesive layer 1. The first adhesive layer 1 is located between the first supporting layer 31 and the second supporting layer 32, and is bonded to the first supporting layer 31 and the second supporting layer 32. The first adhesive layer 1 is provided with a second blocking hole 302, and the second blocking hole 302 penetrates the first adhesive layer 1. A material of the first adhesive layer 1 includes a fluorinated ethylene propylene (FEP) copolymer layer.

On the basis of the above embodiments, as shown in FIGS. 12 to 14, the orthogonal projection of the first blocking hole 301 on the reference plane substantially coincides with the orthogonal projection of the second blocking hole 302 on the reference plane.

With such arrangement, the first blocking hole 301 and the second blocking hole 302 may be formed in a one-step etching process, which may reduce the process steps of the display module 100 and reduce the manufacturing cost of the display module 100.

In some embodiments, as shown in FIGS. 12 to 14, the orthographic projection of the driver chip 40 on the reference plane is located within an orthogonal projection of a blocking hole on the reference plane, and the distance between the boundary of the orthographic projection of the driver chip 40 on the reference plane and the boundary of the orthogonal projection of the blocking hole on the reference plane is greater than or equal to 0.5 mm.

It will be noted that the blocking hole includes the first blocking hole 301 and/or the second blocking hole 302. In addition, the blocking holes mentioned below each include the first blocking hole 301 and/or the second blocking hole 302, which will not be described in detail in the embodiments of the present disclosure.

For example, the distance between the boundary of the orthographic projection of the driver chip 40 on the reference plane and the boundary of the orthogonal projection of the blocking hole on the reference plane is one of 0.5 mm, 0.55 mm, 0.61 mm, 0.7 mm and 0.85 mm.

In this way, the blocking hole may block the deformation of the main body portion 110 from being transmitted to the driver chip 40 to the greatest extent, thereby reducing the risk of deformation of the driver chip 40 and reducing the risk of damage to the driver chip 40.

For example, the orthographic projection of the driver chip 40 on the reference plane is located within the orthogonal projection of the first blocking hole 301 on the reference plane, and the distance between the boundary of the orthographic projection of the driver chip 40 on the reference plane and the boundary of the orthogonal projection of the first blocking hole 301 on the reference plane is greater than or equal to 0.5 mm.

For example, the distance between the boundary of the orthographic projection of the driver chip 40 on the reference plane and the boundary of the orthogonal projection of the first blocking hole 301 on the reference plane is any one of 0.5 mm, 0.55 mm, 0.61 mm, 0.7 mm, and 0.85 mm.

Alternatively, for example, the orthographic projection of the driver chip 40 on the reference plane is located within the orthogonal projection of the second blocking hole 302 on the reference plane, and the distance between the boundary of the orthographic projection of the driver chip 40 on the reference plane and the boundary of the orthogonal projection of the second blocking hole 302 on the reference plane is greater than or equal to 0.5 mm.

For example, the distance the boundary of the orthographic projection of the driver chip 40 on the reference plane and the boundary of the orthogonal projection of the second blocking hole 302 on the reference plane is any one of 0.5 mm, 0.55 mm, 0.61 mm, 0.7 mm, and 0.85 mm.

Alternatively, for example, the orthographic projection of the driver chip on the reference plane is located within the orthogonal projection of the first blocking hole 301 on the reference plane, and the distance between the boundary of the orthographic projection of the driver chip 40 on the reference plane and the boundary of the orthogonal projection of the first blocking hole 301 on the reference plane is greater than or equal to 0.5 mm.

For example, the distance between the boundary of the orthographic projection of the driver chip 40 on the reference plane and the boundary of the orthogonal projection of the first blocking hole 301 on the reference plane is any one of 0.5 mm, 0.55 mm, 0.61 mm, 0.7 mm, and 0.85 mm.

Moreover, the orthographic projection of the driver chip 40 on the reference plane is located within the orthogonal projection of the second blocking hole 302 on the reference plane, and the distance between the boundary of the orthographic projection of the driver chip 40 on the reference plane and the boundary of the orthogonal projection of the second blocking hole 302 on the reference plane is greater than or equal to 0.5 mm.

For example, the distance between the boundary of the orthographic projection of the driver chip 40 on the reference plane and the boundary of the orthogonal projection of the second blocking hole 302 on the reference plane is any one of 0.5 mm, 0.55 mm, 0.61 mm, 0.7 mm, and 0.85 mm.

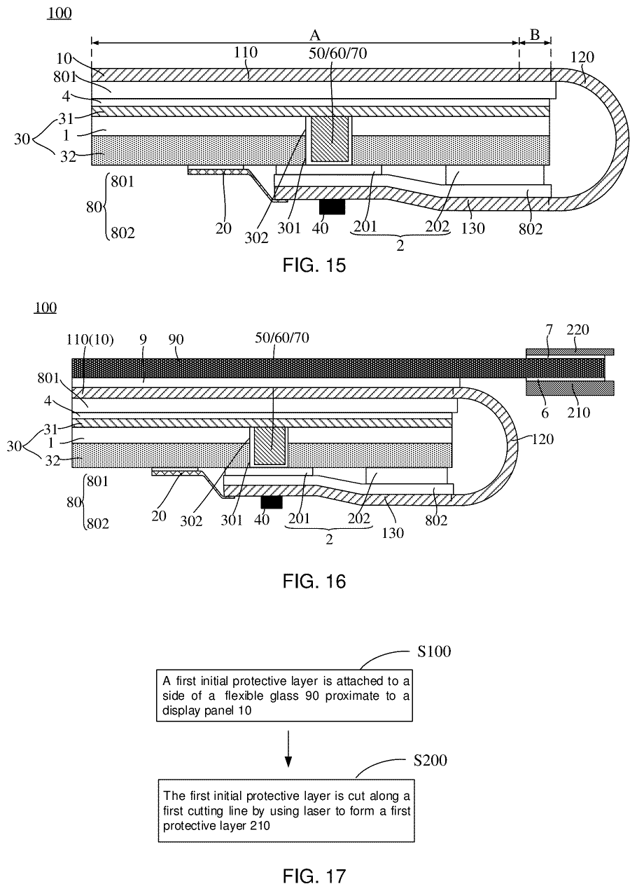

In some embodiments, as shown in FIG. 15, the display module 100 further includes a heat sink 50, and the heat sink 50 is located in the blocking hole, and an orthographic projection of the heat sink 50 on the reference plane at least partially overlaps with the orthographic projection of the driver chip 40 on the reference plane.

In this case, the heat generated by the driver chip 40 may be transferred to the heat sink 50, and the heat sink 50 transfers the heat to the atmosphere, which may improve the heat dissipation efficiency of the driver chip 40 and increase the service life of the driver chip 40.

A material used for the heat sink 50 includes at least one of copper, silver, gold, graphite and boron nitride. For example, the material used for the heat sink 50 includes graphite. Graphite has a high heat dissipation coefficient, which is beneficial to improving the heat dissipation efficiency of the driver chip 40.

In some examples, as shown in FIG. 15, in a direction perpendicular to the main body portion 110, a dimension of the heat sink 50 is less than or equal to a dimension of the blocking hole. That is to say, an end of the heat sink 50 proximate to the bonding portion is farther away from the bonding portion 130 than an end of the blocking hole proximate to the bonding portion 130; alternatively, an end of the heat sink 50 proximate to the bonding portion 130 is substantially flush with an end of the blocking hole proximate to the bonding portion 130.

In this case, it is possible to ameliorate the problem of the deformation of the bonding portion 130 caused by the heat sink 50 protruding out of the blocking hole, so that the risk of the deformation of the driver chip 40 caused by the deformation of the bonding portion 130 may be reduced, and the risk of damage to the driver chip 40 may be reduced.

In some other embodiments, as shown in FIG. 15, the display module 100 further includes an electromagnetic shielding member 60, and the electromagnetic shielding member 60 is located in the blocking hole, and an orthographic projection of the electromagnetic shielding member 60 on the reference plane at least partially overlaps with the orthographic projection of the driver chip 40 on the reference plane.

In this case, the electromagnetic shielding member 60 may reduce the influence of electromagnetic waves outside of the driver chip 40 on the driver chip 40. The material used for the electromagnetic shielding member 60 is a wave-absorbing material. For example, the material used for the electromagnetic shielding member 60 includes at least one of copper, aluminum and nickel.

In some examples, as shown in the figure, in the direction perpendicular to the main body portion 110, the dimension of the electromagnetic shielding member 60 is less than or equal to the dimension of the blocking hole. That is to say, an end of the electromagnetic shielding member 60 proximate to the bonding portion 130 is farther away from the bonding portion 130 than an end of the blocking hole proximate to the bonding portion 130; alternatively, an end of the electromagnetic shielding member 60 proximate to the bonding portion 130 is substantially flush with an end of the blocking hole proximate to the bonding portion 130.

In this case, it is possible to ameliorate the problem of the deformation of the bonding portion 130 caused by the electromagnetic shielding member 60 protruding out of the blocking hole, so that the risk of the deformation of the driver chip 40 caused by the deformation of the bonding portion 130 may be reduced, and the risk of damage to the driver chip 40 may be reduced.

In some other embodiments, as shown in FIG. 15, the display module 100 further includes a buffer member 70, and the buffer member is located in the blocking hole, and an orthographic projection of the buffer member 70 on the reference plane at least partially overlaps with the orthographic projection of the driver chip 40 on the reference plane.

In this case, the buffer member 70 may produce a certain deformation after being subjected to stress (tensile stress or compressive stress), and the stress generated inside it may be released through the deformation of the buffer member 70 itself, which may prevent the deformation generated by the main body portion 110 from being transmitted to the driver chip 40, thereby reducing the risk of deformation of the driver chip 40 and reducing the risk of damage to the driver chip 40. For example, a material of the buffer member 70 includes foam or rubber.

In some examples, as shown in FIG. 15, in a direction perpendicular to the main body portion 110, a dimension of the buffer member 70 is less than or equal to a dimension of the blocking hole. That is to say, an end of the buffer member 70 proximate to the bonding portion 130 is farther away from the bonding portion 130 than an end of the blocking hole proximate to the bonding portion 130; alternatively, an end of the buffer member 70 proximate to the bonding portion 130 is substantially flush with an end of the blocking hole proximate to the bonding portion 130.

In this case, it is possible to ameliorate the problem of the deformation of the bonding portion 130 caused by the buffer member 70 protruding out of the blocking hole, so that the risk of the deformation of the driver chip 40 caused by the deformation of the bonding portion 130 may be reduced, and the risk of damage to the driver chip 40 may be reduced.

In some examples, as shown in FIG. 7, the display module 100 further includes a back film 200, and the back film 200 is disposed on the non-display surface of the display panel 10.

In some examples, as shown in FIGS. 8 to 15, the back film 80 may include, for example, a first back sub-film 801 and a second back sub-film 802, and the first back sub-film 801 and the second back sub-film 802 are disconnected at the bending portion 120.

In a direction perpendicular to the main body portion 110, the first back sub-film 801 at least partially overlaps with the main body portion 110. The second back sub-film 802 at least partially overlaps with the bonding portion 130, and the second back sub-film 802 may be bent along the bonding portion 130 onto the non-display surface 110B of the main body portion 110 of the display panel 10.

In this case, the back film 80 exposes the bending portion 120 of the display panel 10, which may not only reduce a bending resistance of the bending portion 120 of the display panel 10, but also change a position of a stress neutral layer in the bending portion 120 of the display panel 10 during the bending process, so as to avoid damage to the display panel 10.

In some examples, as shown in FIGS. 8 to 15, the orthographic projection of the boundary of the main body portion 110 on the reference plane is located within an orthographic projection of a boundary of the first back sub-film 801 on the reference plane, that is, the first back sub-film 801 covers the main body portion 110, and an end of the first back sub-film 801 proximate to the second back sub-film 802 extends to the bending portion 120. The orthographic projection of the boundary of the bonding portion 130 on the reference plane is located within an orthographic projection of a boundary of the second back sub-film 802 on the reference plane, that is, the second back sub-film 802 covers the bonding portion 130, and an end of the second back sub-film 802 proximate to the first back sub-film 801 extends to the bending portion 120.

In this case, during the bending process of the display panel 10, stress concentration at the junctions of the main body portion 110, the bending portion 120 and the bonding portion 130 may be avoided, thereby reducing the risk of cracks or breakage of the display panel 10 at the junctions of the main body portion 110, the bending portion 120 and the bonding portion 130.

In some embodiments, as shown in FIG. 6, the display panel 10 further includes a black matrix 17, and the black matrix 17 is disposed on a side of the light-emitting device 15 away from the substrate 11.

It will be noted that the black matrix 17 is configured to separate light emitted by different sub-pixels P, and has a function of reducing reflected light generated after the external ambient light enters an interior of the display panel 10.

In addition, as shown in FIG. 6, the display panel 10 further includes a color filter 18, and the color filter 18 is disposed on a side of the light-emitting device 15 away from the substrate 11. In the case where the display panel 10 includes the black matrix 17, the color filter 18 is disposed on a side of the black matrix 17 away from the substrate 11.

It will be noted that the color filter 18 may filter out the light with most wavelength bands in the external ambient light, thereby reducing the reflection intensity of the external ambient light on the display panel 10.

As shown in FIG. 6, the color filter 18 includes a plurality of filter patterns 181; and an orthogonal projection of a pixel opening 16 on the substrate 11 is located within an orthographic projection of a filter pattern 181 on the substrate 11.

Here, as shown in FIG. 6, a shape of the filter pattern 181 may be substantially the same as a shape of the pixel opening 16, or may be different from the shape of the pixel opening 16. FIG. 6 shows an example in which the shape of the filter pattern 181 is substantially the same as the shape of the pixel opening 16.

It will be noted that a material of the filter pattern 181 includes an organic material, for example, a material of a filter pattern 181 includes at least one of poly methyl methacrylate, general purpose polymers of polystyrene, polymer derivatives with phenolic groups, acryloyl polymers, imide polymers, aryl ether polymers, amide polymers, fluorine polymers, parylene polymers, and vinyl alcohol polymers.

In some other embodiments, the display panel 10 may further include a polarizer. The polarizer may be disposed on a side of the light-emitting device 15 away from the substrate 11. The polarizer may be a flexible member.

In this way, by selecting light with a certain polarization direction to pass through the polarizer, the reflection intensity of the external ambient light on the display panel 10 may be reduced.

In some embodiments, as shown in FIG. 16, the display module 100 further includes a flexible glass 90 (ultra-thin glass). The flexible glass 90 refers to glass having a thickness less than or equal to a first threshold; for example, the first threshold is 0.1 mm.

As shown in FIG. 16, the flexible glass 90 is located on the display surface of the main body portion 110, and an orthographic projection of the flexible glass 90 on the reference plane covers an orthographic projection of the display panel 10 on the reference plane. A boundary of the orthographic projection of the flexible glass 90 on the reference plane and a boundary of the orthographic projection of the display panel on the reference plane have a spacing therebetween. That is, the boundary of the flexible glass 90 is beyond the boundary of the display panel 10. The orthographic projection of the flexible glass 90 on the reference plane covering the orthographic projection of the display panel 10 on the reference plane means that the orthographic projection of the flexible glass 90 on the reference plane coincides with the orthographic projection of the display panel 10 on the reference plane. Alternatively, the orthographic projection of the display panel 10 on the reference plane are located within the range of the orthographic projection of the flexible glass 90 on the reference plane.

In this case, when an object collides with the display module 100 or the display module 100 collides with the ground, the object will first hit the flexible glass 90 instead of touching the display panel 10. In this way, the flexible glass 90 may reduce the risk of the damage to the display panel 10 caused by a case that objects outside the display module 100 directly colliding with the display panel 10.

Furthermore, when an object moves in a direction parallel to the main body portion 110, the object will first hit the edge of the flexible glass 90 and will not hit the edge of the display panel 10. In this way, the flexible glass 90 may also reduce the risk of the damage to the display panel 10 caused by a case that objects outside the display module 100 directly hit the edge of the display panel 10.

In addition, in order to bond the flexible glass 90 to the display panel 10, the display module 100 further includes a top optically clear adhesive (TOCA) layer 9. The top optically clear adhesive layer 9 is located between the flexible glass 90 and the display panel 10, and the top optically clear adhesive layer 9 is configured to bond the flexible glass 90 to the display panel 10.

As shown in FIG. 16, the display module 100 further includes a first protective layer 210. The first protective layer 210 is located on a side of the flexible glass 90 proximate to the display panel 10. At least part of the first protective layer 210 is located on an edge portion of the flexible glass 90 that extends beyond the display panel 10. The first protective layer 210 surrounds the display panel 10.

That is to say, at least part region of the edge portion of the flexible glass 90 that extends beyond the display panel 10 is supported, that is, the at least part region of the edge portion of the flexible glass 90 that extends beyond the display panel 10 will not be in a suspended state. When the flexible glass 90 is subjected to a force, the force will be transmitted to the first protective layer 210 through the edge portion of the flexible glass 90 that extends beyond the display panel 10, and then the force will be dispersed to the first protective layer 210. In this way, the risk of the break of the flexible glass 90 caused by stress concentration in the edge portion of the flexible glass 90 that extends beyond the display panel 10 may be reduced.

In some embodiments, as shown in FIG. 16, the outer boundary of the orthographic projection of the first protective layer 210 on the reference plane is located outside the boundary of the orthographic projection of the flexible glass 90 on the reference plane.

In this way, when an object moves in a direction parallel to the main body portion 110, the object will first hit the edge of the first protective layer 210 and will not hit the edge of the flexible glass 90. The first protective layer 210 may reduce the risk of the damage to the display panel 10.

In addition, a distance between an outer boundary of the orthographic projection of the first protective layer 210 on the reference plane and the boundary of the orthographic projection of the flexible glass 90 on the reference plane is greater than or equal to 0.1 mm.

For example, the distance between the outer boundary of the orthographic projection of the first protective layer 210 on the reference plane and the boundary of the orthographic projection of the flexible glass 90 on the reference plane is one of 0.1 mm, 0.15 mm, 0.22 mm, 0.30 mm, 0.42 mm, 0.48 mm and 0.5 mm.

In some embodiments, an elastic modulus of the first protective layer 210 is less than an elastic modulus of the flexible glass 90.

In this case, the first protective layer 210 may be formed by laser cutting.

In some examples, the elastic modulus of the first protective layer 210 is greater than or equal to 3 Gpa.

For example, the elastic modulus of the first protective layer 210 is one of 3 GPa, 3.6 GPa, 4 GPa, 5.3 GPa, 5.8 GPa and 6 GPa.

The elastic modulus of the flexible glass 90 is greater than or equal to 7 Gpa.

For example, the elastic modulus of the flexible glass 90 is one of 7 GPa, 7.5 GPa, 8.1 GPa, 8.9 GPa, 9.5 GPa, and 10 GPa.

For example, the outer boundary of the orthographic projection of the first protective layer 210 on the reference plane coincides with the boundary of the orthographic projection of the flexible glass 90 on the reference plane.

The first protective layer 210 may be formed by the following manufacturing method. As shown in FIG. 17, the manufacturing method of the display apparatus 1000 includes steps S100 to S200.

In S100, a first initial protective layer is attached to a side of the flexible glass 90 proximate to the display panel 10.

The first initial protective layer is at least partially located on the edge portion of the flexible glass 90 that extends beyond the display panel 10, an inner boundary of an orthographic projection of the first initial protective layer on the reference plane is located within the boundary of the orthographic projection of the flexible glass 90 on the reference plane, an outer boundary of the orthographic projection of the first initial protective layer on the reference plane is located outside the boundary of the orthographic projection of the flexible glass 90 on the reference plane, and the first initial protective layer surrounds the display panel 10.

In S200, the first initial protective layer is cut along a first cutting line by using laser to form a first protective layer 210.

The first cutting line is a boundary of the flexible glass 90.

In some embodiments, the material of the first protective layer 210 includes polyimide or polyethylene terephthalate. A thickness of the first protective layer 210 is in a range of 20 μm to 300 μm, inclusive.

For example, the thickness of the first protective layer 210 is one of 20 μm, 30 μm, 34 μm, 38 μm, 42 μm, 45 μm, 51 μm, 55 μm, 60 μm, 100 μm, 150 μm, 210 μm, 260 μm and 300 μm.

On the basis of the above embodiments, in order to bond the first protective layer 210 and the flexible glass 90, as shown in FIG. 16, the display module 100 further includes a sixth adhesive layer 6. The sixth adhesive layer 6 is located between the first protective layer 210 and the flexible glass 90, and is configured to bond the ultra-thin glass and the first protective layer 210. For example, the material of the sixth adhesive layer 6 is pressure-sensitive adhesive. An elastic modulus of the sixth adhesive layer 6 is in a range of 10 Kpa to 50 Kpa, inclusive.

For example, the elastic modulus of the sixth adhesive layer 6 is one of 10 KPa, 11 KPa, 15 KPa, 19 KPa, 20 KPa, 25 KPa, 33 KPa, 39 KPa, 40 KPa, 45 KPa and 50 KPa.

In some embodiments, as shown in FIG. 16, the display module 100 further includes a second protective layer 220. The second protective layer 220 is located on a side of the flexible glass 90 away from the display panel 10 and is arranged along an edge of the flexible glass 90. An outer boundary of an orthographic projection of the second protective layer 220 on the reference plane is located outside the boundary of the orthographic projection of the flexible glass 90 on the reference plane.

In this case, when an object moves in a direction parallel to the main body portion 110, the object will first hit the edge of the second protective layer 220 and will not hit the edge of the flexible glass 90. In this way, the second protective layer 220 may also reduce the risk of the damage to the flexible glass 90 caused by a case that objects outside the display module 100 directly hit the edge of the flexible glass 90.

For example, the distance between the outer boundary of the orthographic projection of the second protective layer 220 on the reference plane and the boundary of the orthographic projection of the flexible glass 90 on the reference plane is greater than or equal to 0.1 mm.

For example, the distance between the outer boundary of the orthographic projection of the second protective layer 220 on the reference plane and the boundary of the orthographic projection of the flexible glass 90 on the reference plane is one of 0.1 mm, 0.15 mm, 0.22 mm, 0.30 mm, 0.42 mm, 0.48 mm and 0.5 mm.

In some embodiments, the elastic modulus of the second protective layer 220 is less than the elastic modulus of the flexible glass 90.

In this case, the second protective layer 220 may be formed by laser cutting.

In some examples, the elastic modulus of the second protective layer 220 is greater than or equal to 3 GPa.

For example, the elastic modulus of the second protective layer 220 is one of 3 GPa, 3.6 GPa, 4 GPa, 5.3 GPa, 5.8 GPa, and 6 GPa.

The elastic modulus of the flexible glass 90 is greater than or equal to 7 Gpa.

For example, the elastic modulus of the flexible glass 90 is one of 7 GPa, 7.5 GPa, 8.1 GPa, 8.9 GPa, 9.5 GPa, and 10 GPa.

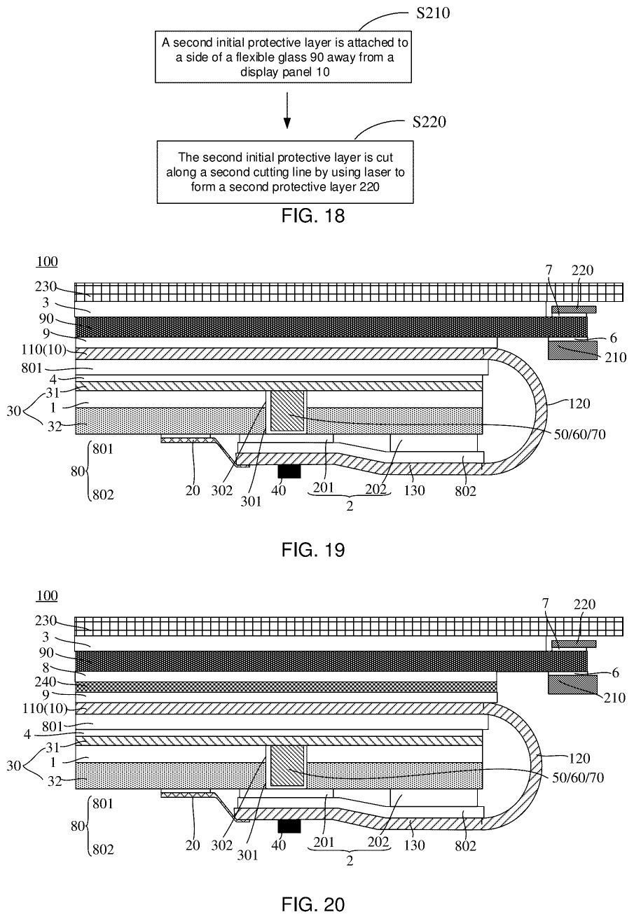

For example, the outer boundary of the orthographic projection of the second protective layer 220 on the reference plane is located outside the boundary of the orthographic projection of the flexible glass 90 on the reference plane. The second protective layer 220 may be formed by the following manufacturing method. As shown in FIG. 18, the manufacturing method of the display apparatus 1000 includes S210 to S220.

In S210, a second initial protective layer is attached to a side of the flexible glass 90 away from the display panel 10.

The second initial protective layer is at least partially located on the edge portion of the flexible glass 90 that extends beyond the display panel 10, an inner boundary of an orthographic projection of the second initial protective layer on the reference plane is located within the boundary of the orthographic projection of the flexible glass 90 on the reference plane, an outer boundary of the orthographic projection of the second initial protective layer on the reference plane is located outside the boundary of the orthographic projection of the flexible glass 90 on the reference plane, and the second initial protective layer surrounds the display panel 10.

In S220, the second initial protective layer 221 is cut along a second cutting line by using laser to form a second protective layer 220.

An edge of the second cutting line is an edge of the second protective layer 220, and the outer boundary of an orthographic projection of the edge of the second protective layer 220 on the reference plane is located outside the boundary of the orthographic projection of the flexible glass 90 on the reference plane.

It will be noted that the above S220 and S200 may be performed in a same process. By configuring in this manner, the processes of the display apparatus 1000 may be reduced, thereby reducing the manufacturing cost of the display apparatus 1000.

For example, as shown in FIG. 16, an outer border of the first protective layer 210 is at least partially substantially flush with an outer border of the second protective layer 220. In the process of forming the protective layer by laser cutting the material, the first protective layer 210 and the second protective layer 220 may be formed simultaneously.

On the basis of the above embodiments, in order to bond the second protective layer 220 and the flexible glass 90, the display module 100 further includes a seventh adhesive layer 7. The seventh adhesive layer 7 is located between the second protective layer 220 and the flexible glass 90, and is configured to bond the flexible glass 90 and the second protective layer 220. For example, the material of the seventh adhesive layer 7 is pressure-sensitive adhesive. An elastic modulus of the seventh adhesive layer 7 is in a range of 10 Kpa to 50 Kpa, inclusive.

For example, the elastic modulus of the seventh adhesive layer 7 is one of 10 KPa, 11 KPa, 15 KPa, 19 KPa, 20 KPa, 25 KPa, 33 KPa, 39 KPa, 40 KPa, 45 KPa and 50 KPa.

In some embodiments, the material of the second protective layer 220 may be the same as the material of the first protective layer 210. For example, the material of the first protective layer 210 and the material of the second protective layer 220 are both polyimide; for another example, the material of the first protective layer 210 and the material of the second protective layer 220 are both polyethylene terephthalate.

Alternatively, the material of the second protective layer 220 may be different from the material of the first protective layer 210. For example, the material of the first protective layer 210 is polyimide, and the material of the second protective layer 220 is polyethylene terephthalate; for another example, the material of the first protective layer 210 includes polyethylene terephthalate, and the material of the second protective layer 220 is polyimide.

In some embodiments, as shown in FIG. 19, the display module 100 further includes a covering layer 230 and a third adhesive layer 3. The covering layer is located on a side of the flexible glass 90 away from the display panel 10, and an orthographic projection of the covering layer 230 on the reference plane covers the orthographic projection of the flexible glass 90 on the reference plane.

In this case, when an object collides with the display module 100 or the display module 100 collides with the ground, the object or the ground will first hit the covering layer 230 and will not hit the flexible glass 90. In this way, the covering layer 230 may reduce the risk of damage to the flexible glass 90 caused by a case that objects outside the display module 100 directly hit the flexible glass 90.

The material of the covering layer 230 includes a colorless polyimide (CPI) film or polyethylene terephthalate.

As shown in FIG. 19, the third adhesive layer 3 is located between the covering layer 230 and the flexible glass 90, and is configured to bond the covering layer 230 and the flexible glass 90. A material of the third adhesive layer 3 is an optically clear adhesive.

For example, an orthographic projection of the third adhesive layer 3 on the reference plane coincides with the orthographic projection of the flexible glass 90 on the reference plane, that is, the size of the third adhesive layer 3 is the same as that of the flexible glass 90.

With such arrangement, the bonding area of the flexible glass 90 may be made large, so that the flexible glass 90 and the covering layer 230 are bonded firmly.

Alternatively, for example, as shown in FIG. 19, the orthographic projection of the third adhesive layer 3 on the reference plane is within the orthographic projection of the flexible glass 90 on the reference plane, and the boundary of the orthographic projection of the third adhesive layer 3 on the reference plane is spaced from the boundary of the orthographic projection of the flexible glass 90 on the reference plane. For example, a distance between the boundary of the orthographic projection of the third adhesive layer 3 on the reference plane and the boundary of the orthographic projection of the flexible glass 90 on the reference plane is greater than 0.3 mm.

For example, the distance between the boundary of the orthographic projection of the third adhesive layer 3 on the reference plane and the boundary of the orthographic projection of the flexible glass 90 on the reference plane is one of 0.3 mm, 0.4 mm, 0.45 mm, 0.5 mm, 0.58 mm, 0.62 mm, 0.66 mm, 0.71 mm, 0.79 mm, 0.8 mm, 0.94 mm and 1 mm.

In this case, an edge portion of the flexible glass 90 that extends beyond the third adhesive layer 3 provides an accommodation space for the second protective layer 220; that is, in the case where the display module 100 includes the second protective layer 220, the second protective layer 220 is at least partially located on the edge portion of the flexible glass 90 that extends beyond the third adhesive layer 3 and surrounds the third adhesive layer 3.

In some embodiments, as shown in FIG. 20, the display module 100 further includes a buffer layer 240 and an eighth adhesive layer 8.

The buffer layer 240 is located between the flexible glass 90 and the display panel 10. The buffer layer 240 mainly plays a role of buffering and shock resistance, so as to improve the impact resistance of the display module 100. A material of the buffer layer 240 includes thermoplastic polyurethane elastomer rubber (TPU).

As shown in FIG. 20, an orthographic projection of the buffer layer 240 on the reference plane may be located within the orthographic projection of the display panel 10 on the reference plane, for example.

As shown in FIG. 20, the eighth adhesive layer 8 is located between the buffer layer 240 and the flexible glass 90, and is configured to bond the buffer layer 240 to the flexible glass 90. The material of the eighth adhesive layer 8 may be the same as that of the third adhesive layer 3; for example, the materials of the third adhesive layer 3 and the eighth adhesive layer 8 are both optically clear adhesive.

On the basis of the above embodiments, a top optically clear adhesive layer 9 is located between the buffer layer 240 and the display panel 10, and is configured to bond the buffer layer 240 and the display panel 10.

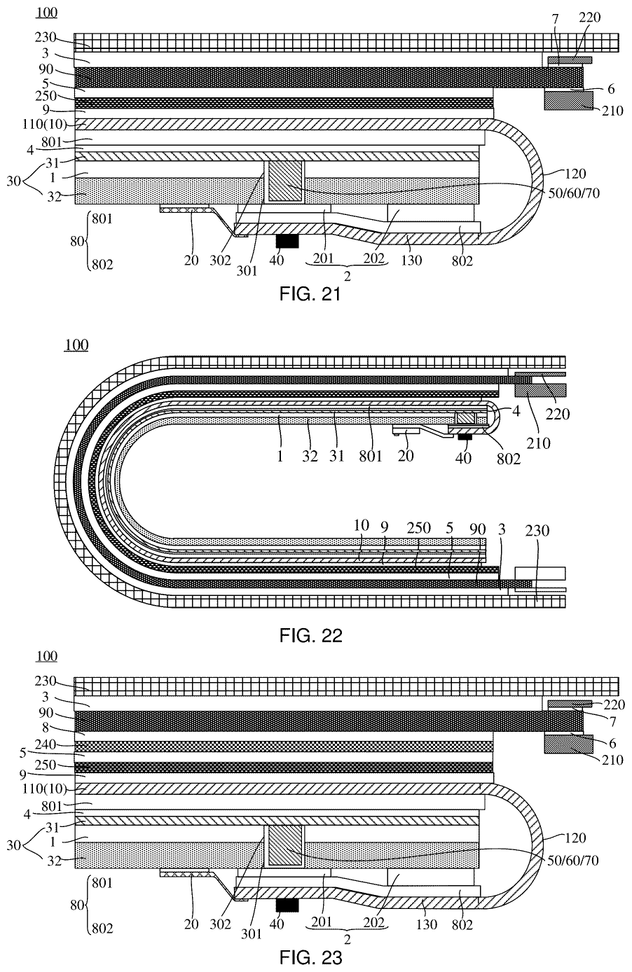

In some other embodiments, as shown in FIGS. 21 and 22, the display module 100 further includes a light shielding layer 250 and a fifth adhesive layer 5.

The light shielding layer 250 is located between the flexible glass 90 and the display panel 10, and is configured to shield ultraviolet light. That is, the light shielding layer 250 mainly serves to reduce the risk of aging of organic materials in the display panel 10. The material of the light shielding layer 250 may include ultraviolet-shielding optically clear adhesive or polyethylene terephthalate.

As shown in FIG. 21, an orthographic projection of the light shielding layer 250 on the reference plane may be located within the orthographic projection of the display panel 10 on the reference plane, for example.

As shown in FIG. 21, the fifth adhesive layer 5 is located between the light shielding layer 250 and the flexible glass 90, and is configured to bond the light shielding layer 250 to the flexible glass 90. A material of the fifth adhesive layer 5 may be the same as that of the third adhesive layer 3; for example, the materials of the third adhesive layer 3 and the fifth adhesive layer 5 are both optically clear adhesive.

On the basis of the above embodiments, the top optically clear adhesive layer 9 is located between the light shielding layer 250 and the display panel 10, and is configured to bond the light shielding layer 250 and the display panel 10.

In some embodiments, as shown in FIG. 23, the display module 100 further includes a buffer layer 240, an eighth adhesive layer 8, a light shielding layer 250 and a fifth adhere layer 5.

The buffer layer 240 is located between the flexible glass 90 and the display panel 10. The eighth adhesive layer 8 is located between the buffer layer 240 and the flexible glass 90, and is configured to bond the buffer layer 240 and the flexible glass 90. The light shielding layer 250 is located between the buffer layer 240 and the display panel 10. The fifth adhesive layer 5 is located between the buffer layer 240 and the light shielding layer 250, and is configured to bond the buffer layer 240 and the light shielding layer 250.

On the basis of the above embodiments, a top optically clear adhesive layer 9 is located between the light shielding layer 250 and the display panel 10, and is configured to bond the light shielding layer 250 and the display panel 10.

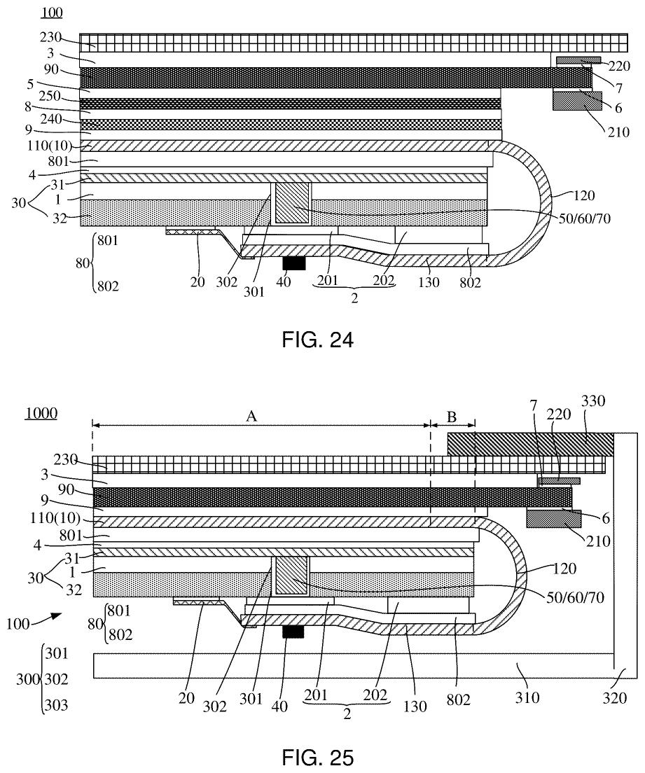

In some embodiments, as shown in FIG. 24, the display module 100 further includes a light shielding layer 250, a fifth adhesive layer 5, a buffer layer 240 and an eighth adhesive layer 8.

The light shielding layer 250 is located between the flexible glass 90 and the display panel 10. The fifth adhesive layer 5 is located between the light shielding layer 250 and the flexible glass 90, and is configured to bond the light shielding layer 250 and the flexible glass 90. The buffer layer 240 is located between the light shielding layer 250 and the display panel 10. The eighth adhesive layer 8 is located between the buffer layer 240 and the light shielding layer 250, and is configured to bond the buffer layer 240 and the light shielding layer 250.

On the basis of the above embodiments, a top optically clear adhesive layer 9 is located between the buffer layer 240 and the display panel 10, and is configured to bond the buffer layer 240 and the display panel 10.

For example, as shown in FIG. 25, the display apparatus 1000 further includes a housing 300, and the display module 100 may be disposed in the housing 300.

The housing 300 includes a bottom plate 310, a side frame 320 and a top frame 330. The bottom plate 310 is located on the non-display surface of the display module 100; the side frame 320 surrounds the bottom plate 310 and is arranged around a periphery of the display module 100; the top frame 330 is located on the display surface of the display module 100, and the top frame 330 is arranged in a ring shape along the edge of the flexible glass 90 of the display module 100.

It will be understood that, as shown in FIG. 25, the display module 100 has a display surface and a non-display surface that are arranged opposite to each other. It will be noted that the display surface 110A refers to a surface (an upper surface of the display module in FIG. 25) of the display module 100 that displays images, and the non-display surface refers to a surface (a lower surface of the display module in FIG. 25) opposite to the display surface.

In some examples, as shown in FIG. 25, an outer boundary of an orthographic projection of the top frame 330 on the reference plane substantially coincides with an inner boundary of an orthographic projection of the side frame 320 on the reference plane, and the top frame 330 is connected to an inner side surface of the side frame 320.

With such arrangement, the side frame 320 may protect the edge of the side frame 320 to reduce the risk of being broken by accidental collisions.

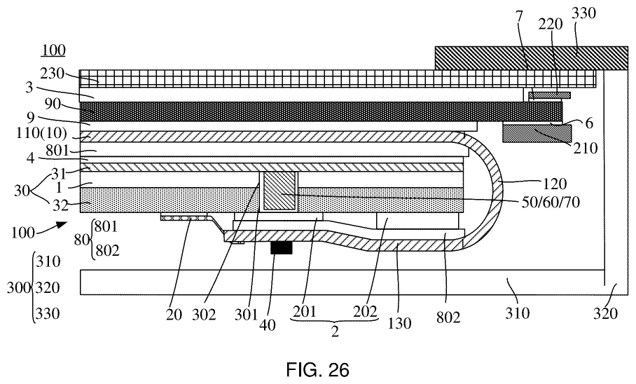

In some other examples, as shown in FIG. 26, an orthographic projection of the side frame 320 on the reference plane is within an orthographic projection of the top frame 330 on the reference plane, and the top frame 330 is connected to an end surface of the side frame 320 away from the bottom plate 310. With such arrangement, the side frame 320 may provide support for the top frame 330.

In addition, the first protective layer 210 at least partially abuts the top frame 330. In this case, when the user applies force to the top frame 330, the force may be transferred to the flexible glass 90, and then transferred to the first protective layer 210, which may reduce the risk of damage to the flexible glass 90 caused by a case that the force on the top frame 330 is transferred to the flexible glass 90.

It will be noted that the term “abut” should be understood in a broad sense, and may refer to a fixed connection, a detachable connection, or abutment or attachment. Furthermore, the term “abut” may be refer to direct abutment, i.e., there is no other component (or region, layer, part) between two components (or regions, layers, parts), or indirect abutment through an intermediate medium, i.e., there is another component (or region, layer, part) between the two components (or regions, layers, parts).

In some embodiments, as shown in FIGS. 25 and 26, the inner boundary of the orthographic projection of the top frame 330 on the reference plane is located within the orthographic projection of the flexible glass 90 on the reference plane, and the distance between the inner boundary of the orthographic projection of the top frame 330 on the reference plane and the orthographic projection of the flexible glass 90 on the reference plane is greater than or equal to 2 mm.

For example, the distance between the inner boundary of the orthographic projection of the top frame 330 on the reference plane and the boundary of the orthographic projection of the flexible glass 90 on the reference plane is one of 2 mm, 2.5 mm, 3.1 mm, 4.5 mm and 5 mm.

In this case, the bonding area between the flexible glass 90 and the top frame 330 is large, which may improve the supporting strength of the top frame 330 for the flexible glass 90.

In some embodiments, as shown in FIG. 25, the inner boundary of the orthographic projection of the top frame 330 on the reference plane is located within an orthographic projection of the peripheral area B on the reference plane.

With such arrangement, the distance between the boundary of the orthographic projection of the peripheral area B on the reference plane and the outer boundary of the orthographic projection of the top frame 330 on the reference plane may be shortened, i.e., the size of the bezel of the display apparatus 1000 may be shortened, so that the screen-to-body ratio of the display apparatus 1000 may be improved.

For example, the inner boundary of the orthographic projection of the top frame 330 on the reference plane coincides with the boundary of the orthographic projection of the peripheral area B on the reference plane. In this case, the size of the bezel of the display apparatus 1000 may be shortened to the greatest extent.

In the case where the bending radius of the display apparatus 1000 is 3 mm, the performance index of the display apparatus 1000 may meet the following requirements: in the case where the temperature is −20 °C, the display apparatus 1000 may be bent for more than or equal to 20,000 times; in the case where the temperature is 25 °C, the display apparatus 1000 may be bent more than or equal to 300,000 times; in the case where the temperature is 85 °C, the display apparatus 1000 may be bent more than or equal to 20,000 times. The surface hardness of the display apparatus 1000 is greater than or equal to 3 H. During the ball drop test, the mass of the falling ball is 32.65 g, and the height of the falling ball is greater than or equal to 15 mm.

In the description of the present specification, specific features, structures, materials or characteristics may be combined in any one or more embodiments or examples in a suitable manner.

The above are only specific embodiments of the present disclosure, but the protection scope of the present disclosure is not limited thereto, and variations or substitutions that any person skilled in the art may conceive of within the technical scope disclosed by the present disclosure, should fall within the protection scope of the present disclosure. Therefore, the protection scope of the present disclosure should be determined by the protection scope of the claims.

1. A display module, comprising:
a display panel including a main body portion, a bonding portion, and a bending portion between the main body portion and the bonding portion; wherein the main body portion has a display surface and a non-display surface arranged opposite to each other, and the bending portion is bent toward the non-display surface of the main body portion, so that the bonding portion is bent onto the non-display surface of the main body portion;
one or more supporting layers located between the main body portion and the bonding portion, and connected to the main body portion and the bonding portion; wherein at least one supporting layer of the one or more supporting layers is provided with a first blocking hole therein; and
a driver chip located on the bonding portion and on a side of the bonding portion away from the main body portion; wherein an orthographic projection of the driver chip on a reference plane at least partially overlaps with an orthogonal projection of the first blocking hole on the reference plane, the reference plane is a plane where the display surface of the main body portion of the display panel is located.

2. The display module according to claim 1, wherein the display module comprises a plurality of supporting layers, the display module further comprises:
one or more adhesive layers, wherein two adjacent supporting layers in the plurality of supporting layers have an adhesive layer of the one or more adhesive layers therebetween; among the one or more adhesive layers, at least one adhesive layer is provided with a second blocking hole therein; the orthographic projection of the driver chip on the reference plane at least partially overlaps with an orthogonal projection of the second blocking hole on the reference plane.

3. The display module according to claim 2, wherein in a direction perpendicular to the main body portion and from the main body portion to the bonding portion, the plurality of supporting layers include a first supporting layer and a second supporting layer, a density of the first supporting layer is greater than a density of the second supporting layer; the second supporting layer is provided with the first blocking hole therein, and the first blocking hole penetrates the second supporting layer;
the one or more adhesive layers include a first adhesive layer, and the first adhesive layer is located between the first supporting layer and the second supporting layer; the first adhesive layer is provided with the second blocking hole therein, and the second blocking hole penetrates the first adhesive layer.

4. The display module according to claim 3, wherein the orthogonal projection of the first blocking hole on the reference plane substantially coincides with the orthogonal projection of the second blocking hole on the reference plane.

5. The display module according to claim 1, wherein the orthographic projection of the driver chip on the reference plane is located within an orthogonal projection of a blocking hole on the reference plane, the blocking hole including the first blocking hole; and
a distance between a boundary of the orthographic projection of the driver chip on the reference plane and a boundary of the orthogonal projection of the blocking hole on the reference plane is greater than or equal to 0.5 mm.

6. The display module according to claim 1, further comprising:
a heat sink located in a blocking hole, wherein the blocking hole includes the first blocking hole, and an orthographic projection of the heat sink on the reference plane at least partially overlaps with the orthographic projection of the driver chip on the reference plane.

7. The display module according to claim 1, further comprising:
an electromagnetic shielding member located in a blocking hole, wherein the blocking hole includes the first blocking hole, and an orthographic projection of the electromagnetic shielding member on the reference plane at least partially overlaps with the orthographic projection of the driver chip on the reference plane.

8. The display module according to claim 1, further comprising:
a buffer member located in a blocking hole, wherein the blocking hole includes the first blocking hole, and an orthographic projection of the buffer member on the reference plane at least partially overlaps with the orthographic projection of the driver chip on the reference plane.

9. The display module according to claim 1, further comprising:
a second adhesive layer including a first adhesive pattern and a second adhesive pattern, wherein the first adhesive pattern is located between the one or more supporting layer and the bonding portion, and the second adhesive pattern is located between the one or more supporting layers and the bonding portion and between the first adhesive pattern and the bending portion; a thickness of the second adhesive pattern is greater than a thickness of the first adhesive pattern, and the second adhesive pattern and the first adhesive pattern have a spacing therebetween;
wherein the driver chip is arranged on a side of the first adhesive pattern away from the main body portion.

10. The display module according to claim 1, further comprising:
a flexible glass located on the display surface of the main body portion, wherein an orthographic projection of the flexible glass on the reference plane covers an orthographic projection of the display panel on the reference plane, and a boundary of the orthographic projection of the flexible glass on the reference plane and a boundary of the orthographic projection of the display panel on the reference plane have a spacing therebetween; and
a first protective layer located on a side of the flexible glass proximate to the display panel, wherein the first protective layer is at least partially located on an edge portion of the flexible glass that extends beyond the display panel, and the first protective layer surrounds the display panel.

11. The display module according to claim 10, wherein an outer boundary of an orthographic projection of the first protective layer on the reference plane is located outside the boundary of the orthographic projection of the flexible glass on the reference plane.

12. The display module according to claim 10, wherein an elastic modulus of a material of the first protective layer is less than an elastic modulus of the flexible glass.

13. The display module according to claim 10, further comprising:
a second protective layer located on a side of the flexible glass away from the display panel and arranged along an edge of the flexible glass, wherein an outer boundary of an orthographic projection of the second protective layer on the reference plane is located outside the boundary of the orthographic projection of the flexible glass on the reference plane.

14. The display module according to claim 13, wherein a distance between an outer boundary of an orthographic projection of the first protective layer on the reference plane and the boundary of the orthographic projection of the flexible glass on the reference plane is greater than or equal to 0.1 mm; and/or
a distance between the outer boundary of the orthographic projection of the second protective layer on the reference plane and the boundary of the orthographic projection of the flexible glass on the reference plane is greater than or equal to 0.1 mm.

15. The display module according to claim 13, wherein an outer border of the first protective layer is at least partially substantially flush with an outer border of the second protective layer.

16. (canceled)

17. The display module according to claim 1, further comprising:
a covering layer located on a side of the flexible glass away from the display panel, wherein an orthographic projection of the covering layer on the reference plane covers the orthographic projection of the flexible glass on the reference plane; and
a third adhesive layer located between the covering layer and the flexible glass, wherein an orthographic projection of the third adhesive layer on the reference plane is located within the orthographic projection of the flexible glass on the reference plane, and a boundary of the orthographic projection of the third adhesive layer on the reference plane and the boundary of the orthographic projection of the flexible glass on the reference plane have a spacing therebetween; and
a second protective layer located on a side of the flexible glass away from the display panel and arranged along an edge of the flexible glass, wherein the second protective layer is at least partially located on an edge portion of the flexible glass that extends beyond the third adhesive layer and surrounds the third adhesive layer.

18. The display module according to claim 10, further comprising:
a buffer layer located between the flexible glass and the display panel; and/or
a light shielding layer located between the flexible glass and the display panel, the light shielding layer being configured to shield ultraviolet light.

19. A display apparatus, comprising:
the display module according to claim 1; and
a housing, wherein the display module is located inside the housing.

20. The display apparatus according to claim 19, wherein the housing includes a bottom plate, a side frame and a top frame; the bottom plate is located on the non-display surface of the display module; the side frame surrounds the bottom plate and is arranged around a periphery of the display module; the top frame is located on the display surface of the display module, the top frame is arranged in a shape of an annulus along an edge of a flexible glass of the display module.

21. The display apparatus according to claim 20, wherein an inner boundary of an orthographic projection of the top frame on the reference plane is located within an orthographic projection of the flexible glass on the reference plane, and a distance between the inner boundary of the orthographic projection of the top frame on the reference plane and a boundary of the orthographic projection of the flexible glass on the reference plane is greater than or equal to 2 mm; and/or
the main body portion of the display panel in the display module has display area and a peripheral area surrounding the display area, and the inner boundary of orthographic projection of the top frame on the reference plane located within an orthographic projection of the peripheral area on the reference plane.

22. (canceled)
